(19) United States
(12) Patent Application Publication
(10) Pub. No.: US 2021/0273055 A1
(43) Pub. Date: Sep. 2, 2021

(54) SEMICONDUCTOR STORAGE DEVICE AND MANUFACTURING METHOD THEREOF

(71) Applicant: Kioxia Corporation, Tokyo (JP)

(72) Inventors: Naomi YANAI, Kuwana (JP); Yasuhito YOSHIMIZU, Yokkaichi (JP); Takashi ISHIDA, Yokkaichi (JP)

(73) Assignee: Kioxia Corporation, Tokyo, JAPAN

(21) Appl. No.: 17/019,683

(22) Filed: Sep. 14, 2020

(30) Foreign Application Priority Data
Feb. 27, 2020 (JP) 2020-031962

(51) Int. Cl. H01L 29/10; H01L 27/11524; H01L 27/11556; H01L 27/1157; H01L 27/11582; H01L 29/423; H01L 29/66; H01L 29/792; H01L 29/788

(52) U.S. Cl. CPC H01L 29/1041; H01L 27/11524; H01L 27/11556; H01L 27/1157; H01L 27/11582; H01L 29/7889; H01L 29/42328; H01L 29/66833; H01L 29/66825; H01L 29/7926; H01L 29/42344

(57) ABSTRACT

A semiconductor storage device according to the present embodiment includes a first semiconductor layer containing impurities. A stacked body is provided above the first semiconductor layer and includes insulating layers and conductive layers that are alternately stacked. A semiconductor body penetrates through the stacked body in a stacking direction to reach the first semiconductor layer and includes a lower region on a side of the first semiconductor layer and an upper region positioned above the lower region. A charge accumulation part is provided between the semiconductor bodies and the conductive layers. An impurity concentration of the lower region of the semiconductor body is higher than that of the first semiconductor layer.

### CROSS REFERENCE TO RELATED APPLICATIONS

This application is based upon and claims the benefit of priority from the prior Japanese Patent Application No. 2020-031962, filed on Feb. 27, 2020, the entire contents of which are incorporated herein by reference.

### FIELD

The embodiments of the present invention relate to a semiconductor storage device and manufacturing method thereof.

### BACKGROUND

Semiconductor storage devices, such as a NAND flash memory, having a three-dimensional memory cell array in which memory cells are three-dimensionally arrayed have been developed. In these semiconductor storage devices, holes are sometimes supplied to channel regions by GIDL (Gate Induced Drain Leakage) occurring at bottoms of memory holes to perform an erase operation. In order to efficiently generate the GIDL, a steep voltage gradient needs to be formed at the bottoms of the memory holes. For this purpose, a highly-concentrated impurity layer needs to be formed in the channel regions at the bottoms of the memory holes.

However, it is difficult to form a highly-concentrated impurity layer having a steep concentration gradient at the bottoms of memory holes having a high aspect ratio.

### BRIEF DESCRIPTION OF THE DRAWINGS

FIG. 1 is a schematic perspective view of a memory cell array according to a first embodiment;

FIG. 2 is a schematic sectional view of the memory cell array;

FIG. 3A is an enlarged sectional view of a portion in a dashed frame A in FIG. 2;

FIG. 3B is an enlarged sectional view of a portion in a dashed frame B in FIG. 2; and

FIGS. 4 to 20 are sectional views illustrating an example of the manufacturing method of the semiconductor storage device according to the first embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction perpendicular to a surface of a semiconductor substrate on which semiconductor elements are provided is assumed as “an upper direction”. Therefore, the term “upper direction” or “lower direction” occasionally differs from an upper direction or a lower direction based on a gravitational acceleration direction. In the present specification and the drawings, elements identical to those described in the foregoing drawings are denoted by like reference characters and detailed explanations thereof are omitted as appropriate.

A semiconductor storage device according to the present embodiment includes a first semiconductor layer containing impurities. A stacked body is provided above the first semiconductor layer and includes insulating layers and conductive layers that are alternately stacked. A semiconductor body penetrates through the stacked body in a stacking direction to reach the first semiconductor layer and includes a lower region on a side of the first semiconductor layer and an upper region positioned above the lower region. A charge accumulation part is provided between the semiconductor bodies and the conductive layers. An impurity concentration of the lower region of the semiconductor body is higher than that of the first semiconductor layer.

In the embodiment, a semiconductor storage device having a memory cell array with a three-dimensional structure is explained as an example of semiconductor devices.

### FIRST EMBODIMENT

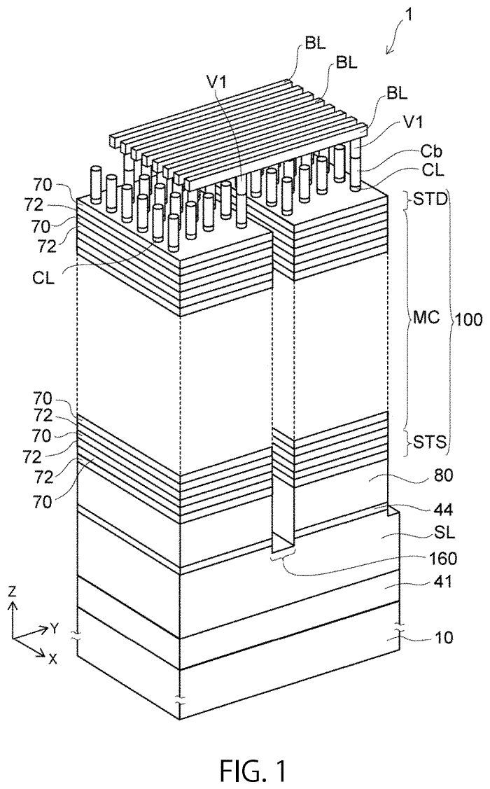

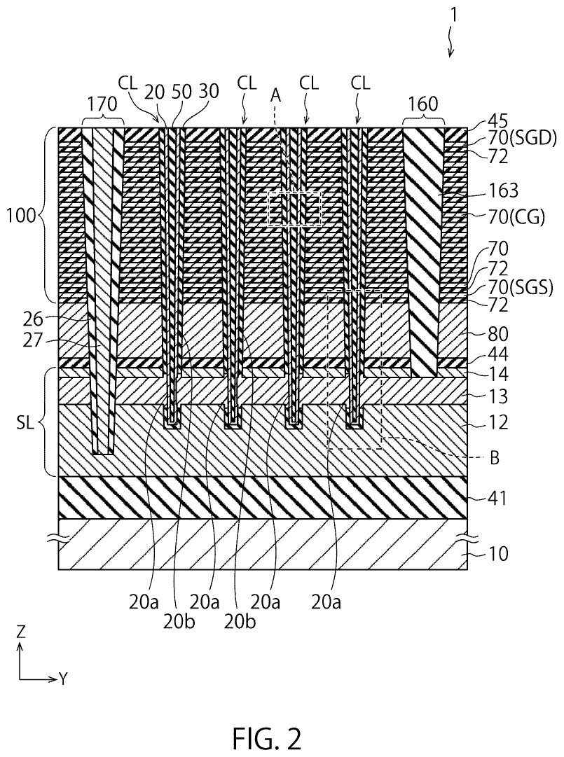

FIG. 1 is a schematic perspective view of a memory cell array 1 according to a first embodiment. FIG. 2 is a schematic sectional view of the memory cell array 1.

In FIG. 1, two directions being parallel to the principal surface of a substrate 10 and being orthogonal to each other are assumed as an X-direction and a Y-direction, and a direction orthogonal to both the X-direction and the Y-direction is assumed to be a Z-direction (a stacking direction). A Y-direction and a Z-direction in FIG. 2 correspond to the Y-direction and the Z-direction in FIG. 1, respectively.

The memory cell array 1 includes a source layer SL, a stacked body 100 provided above the source layer SL, a gate layer 80 provided between the source layer SL and the stacked body 100, a plurality of columnar parts CL, a plurality of insulating parts 160, and a plurality of bit lines BL provided above the stacked body 100. The source layer SL is positioned above the substrate 10 with an insulating layer 41 interposed therebetween. The substrate 10 is, for example, a silicon substrate.

The columnar parts CL are substantially cylindrical parts penetrating through the stacked body 100 in the stacking direction (the Z-direction). The columnar parts CL further penetrate through the gate layer 80 under the stacked body 100 to reach the source layer SL (semiconductor layers 12 and 13 in FIG. 2). The columnar parts CL are arrayed, for example, in a staggered manner in a planar layout. The columnar parts CL may be arrayed in a square lattice along the X-direction and the Y-direction in the planar layout.

As illustrated in FIG. 2, the insulating parts 160 divide the stacked body 100 and the gate layer 80 into a plurality of blocks (or finger parts) in the Y-direction. The insulating parts 160 have a structure in which an insulating film 163 is embedded in slits ST, which will be described later.

Wiring parts 170 electrically connect the stacked body 100 and the gate layer 80 to the semiconductor layer 12 while dividing the stacked body 100 and the gate layer 80 into a plurality of blocks (or finger parts) in the Y-direction. The wiring parts 170 are formed in slits ST, similarly to the insulating parts 160. An insulating film 26 is provided on inner surfaces of the slits ST, and a wiring layer 27 of a conductive material such as doped polysilicon or tungsten is provided inside the insulating film 26. The insulating film 26 electrically insulates the wiring layer 27 from the stacked body 100 and the gate layer 80 of the memory cell array 1 and connects the wiring layer 27 to the semiconductor layer 12 at the bottoms of the slits ST. Accordingly, the wiring parts 170 function as electrical contacts extending from an upper part of the memory cell array 1 to the semiconductor layer 12 (the source layer SL).

The bit lines BL are, for example, metallic films extending in the Y-direction. The bit lines BL are separated from each other in the X-direction.

Upper end portions of semiconductor bodies 20, which will be described later, of the columnar parts CL are connected to the bit lines BL with contacts Cb and contacts (vias) V1 illustrated in FIG. 1.

As illustrated in FIG. 2, the source line SL includes the semiconductor layers 12 and 13 and a semiconductor layer 14. The source layer SL is provided on the insulating layer 41.

In the source layer SL, the semiconductor layer 13 is located on the semiconductor layer 12, and the semiconductor layer 14 is located on the semiconductor layer 13.

The semiconductor layers 12 to 14 are polycrystalline silicon layers including impurities and having conductivity. The semiconductor layers 12 to 14 are n-type polycrystalline silicon layers, for example, having phosphorus or arsenic doped thereto as a conductive material. The semiconductor layer 14 may be an undoped polycrystalline silicon layer to which impurities are not intentionally doped. The thickness of the semiconductor layer 14 is smaller than that of the semiconductor layer 12 and that of the semiconductor layer 13.

An insulating layer 44 is provided on the semiconductor layer 14 and the gate layer 80 is provided on the insulating layer 44. The gate layer 80 is positioned between the semiconductor layer 13, 14 and the stacked body 100 and functions as parts of source-side selection gates SGS. The gate layer 80 is a polycrystalline silicon layer including impurities and having conductivity. The gate layer 80 can be, for example, an n-type polycrystalline silicon layer having phosphorus or arsenic doped thereto, or a metal gate such as tungsten. The thickness of the gate layer 80 is larger than that of the semiconductor layer 14.

The stacked body 100 is provided on the gate layer 80. The stacked body 100 has a plurality of electrode layers 70 stacked in a direction (the Z-direction) perpendicular to the principal surface of the substrate 10. An insulating layer 72 is provided between ones of the electrode layers 70 adjacent in the vertical direction. That is, the stacked body 100 is formed by alternately stacking the insulating layers 72 and the electrode layers 70 above the semiconductor layer 13. An insulating layer 72 is provided between the bottommost electrode layer 70 and the gate layer 80. An insulating layer 45 is provided on the topmost electrode layer 70.

The electrode layers 70 are conductive metal layers. The electrode layers 70 are, for example, tungsten layers containing tungsten as a primary component or a molybdenum layer containing molybdenum as a primary component. For example, TiN/Ti may be included as a barrier metal layer in the electrode layers 70. The insulating layers 72 are silicon dioxide layers containing oxide silicon as a primary component.

At least the topmost electrode layer 70 among the electrode layers 70 is drain-side selection gates SGD of drain-side selection transistors STD (FIG. 1) and at least the bottommost electrode layer 70 is parts of source-side selection gates SGS of source-side selection transistors STS (FIG. 1). For example, a plurality of (for example, three) electrode layers 70 on the lower layer side including the bottommost electrode layer 70 are the source-side selection gates SGS. Therefore, the source-side selection gates SGS are constituted by the gate layer 80 and one electrode layer 70 or plural electrode layers 70 on the bottommost layer side. The drain-side selection gates SGD may also be provided in a plurality of layers.

A plurality of the electrode layers 70 are provided as cell gates CG between the drain-side selection gates SGD and the source-side selection gates SGS.

The gate layer 80 is thicker than one electrode layer 70 and thicker than one insulating layer 72. Therefore, the gate layer 80 is thicker than one layer of the drain-side selection gates SGD, thicker than one layer of the source-side selection gates SGS, and thicker than one layer of the cell gates CG.

The columnar parts CL extend through the stacked body 100 in the stacking direction and further penetrate through the gate layer 80, the insulating layer 44, the semiconductor layer 14, and the semiconductor layer 13 to reach the semiconductor layer 12.

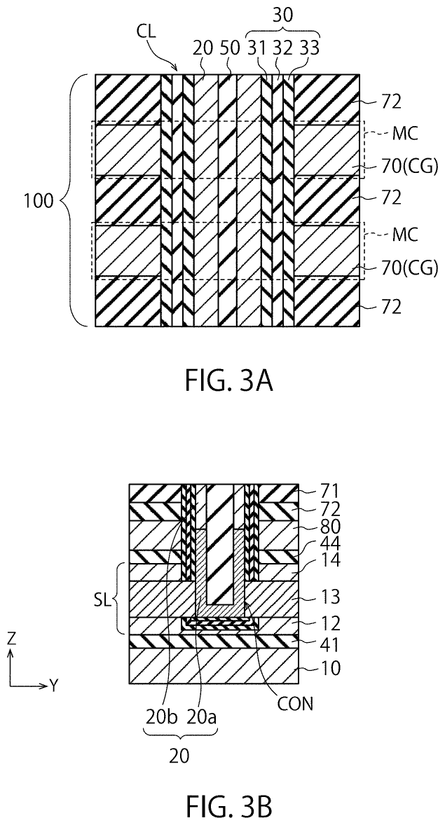

FIG. 3A is an enlarged sectional view of a portion in a dashed frame A in FIG. 2.

Each of the columnar parts CL includes a memory film 30, the semiconductor body 20, and an insulating core film 50. The memory film 30 is a stacked film of insulating films including a tunnel dielectric film 31, a charge accumulation film (charge accumulation part) 32, and a block dielectric film 33.

As illustrated in FIG. 2, the semiconductor body 20 is formed in the shape of a pipe continuously extending in the stacked body 100 and the gate layer 80 in the Z-direction to reach the source layer SL. The core film 50 is provided inside the semiconductor body 20 in the pipe shape.

The upper end portion of the semiconductor body 20 is connected to the corresponding bit line BL with the contact Cb and the contact V1 illustrated in FIG. 1. A lower region 20a of the semiconductor body 20 on the lower end side is in contact with the semiconductor layer 13 of the source layer SL.

The memory film 30 is provided between the stacked body 100 and the semiconductor body 20 and between the gate layer 80 and the semiconductor body 20, and surrounds the semiconductor body 20 from the outer circumferential side.

The memory film 30 continuously extends in the stacked body 100 and the gate layer 80 in the Z-direction. The memory film 30 is not provided in the lower region (source contact part) 20a of the semiconductor body 20, which is in contact with the semiconductor layer 13. The lower region 20a is not covered with the memory film 30. The memory film 30 may be placed on a part of the outer circumference of the semiconductor body 20 between the semiconductor body 20 and the semiconductor layer 13.

The lower end portion of the semiconductor body 20 is positioned below the lower region 20a continuously with the lower region 20a, and is located in the semiconductor layer 12. The memory film 30 is provided between the lower end portion of the semiconductor body 20 and the semiconductor layer 12. Therefore, the memory film 30 is divided in the Z-direction at the location of the lower region 20a of the semiconductor body 20 and is placed therebelow at a location surrounding the outer circumference of the lower end portion of the semiconductor body 20 and under the bottom surface of the semiconductor body 20.

As illustrated in FIG. 3A, the tunnel dielectric film 31 is provided between the semiconductor body 20 and the charge accumulation film 32 and is in contact with the semiconductor body 20. The charge accumulation film 32 is positioned between the semiconductor body 20 and the electrode layers 70 and is provided between the tunnel dielectric film 31 and the block dielectric film 33. The block dielectric film 33 is provided between the charge accumulation film 32 and the electrode layers 70.

The semiconductor body 20, the memory film 30, and the electrode layers 70 (the cell gates CG) form memory cells MC. Each of the memory cells MC has a vertical transistor structure in which the semiconductor body 20 is surrounded by the corresponding electrode layer 70 (the cell gate CG) with the memory film 30 interposed therebetween.

In the memory cells MC with the vertical transistor structure, the semiconductor body 20 is, for example, a silicon channel body and the electrode layer 70 (the cell gate CG) functions as a control gate. The charge accumulation film 32 functions as a data storage layer that has charges input from the semiconductor body 20 accumulated therein.

The semiconductor storage device according to the embodiment is a non-volatile semiconductor storage device that can freely electrically erase and write data and can retain stored contents even when the power is turned off.

The memory cells MC are, for example, charge-trapping memory cells. The charge accumulation film 32 has many trapping sites that trap charges in an insulating film and includes, for example, a silicon nitride film. Alternatively, the charge accumulation film 32 may be a conductive floating gate surrounded by an insulator.

The tunnel dielectric film 31 serves as a potential barrier when charges are input from the semiconductor body 20 to the charge accumulation film 32 or when charges accumulated in the charge accumulation film 32 are emitted to the semiconductor body 20. The tunnel dielectric film 31 includes, for example, a silicon dioxide film.

The block dielectric film 33 prevents charges accumulated in the charge accumulation film 32 from being emitted to the electrode layers 70. The block dielectric film 33 also prevents back tunneling of charges from the electrode layers 70 to the columnar part CL.

The block dielectric film 33 includes, for example, a silicon dioxide film. Alternatively, the block dielectric film 33 may have a stacked structure including a silicon dioxide film and a metal oxide film. In this case, the silicon dioxide film can be positioned between the charge accumulation film 32 and the metal oxide film and the metal oxide film can be positioned between the silicon dioxide film and the electrode layers 70. The metal oxide film is, for example, an aluminum oxide film.

As illustrated in FIG. 1, the drain-side selection transistors STD are provided in an upper layer part of the stacked body 100. The source-side selection transistors STS are provided in a lower layer part of the stacked body 100.

The drain-side selection transistors STD are vertical transistors each having the drain-side selection gate SGD (FIG. 2) described above as a control gate, and the source-side selection transistors STS are vertical transistors each having the source-side selection gate SGS (FIG. 2) described above as a control gate.

A portion of each of the semiconductor bodies 20 facing the drain-side selection gate SGD functions as a channel and the memory film 30 between the channel and the drain-side selection gate SGD functions as a gate dielectric film of the drain-side selection transistor STD.

A portion of each of the semiconductor bodies 20 facing the source-side selection gate SGS functions as a channel and the memory film 30 between the channel and the source-side selection gate SGS functions as a gate dielectric film of the source-side selection transistor STS.

A plurality of drain-side selection transistors STD connected in series via the semiconductor body 20 may be provided, or a plurality of source-side selection transistors STS connected in series via the semiconductor body 20 may be provided. A same gate potential is applied to the drain-side selection gates SGD of the drain-side selection transistors STD, and a same gate potential is applied to the source-side selection gates SGS of the source-side selection transistors STS.

A plurality of memory cells MC are provided between the drain-side selection transistor STD and the source-side selection transistor STS. The memory cells MC, the drain-side selection transistor STD, and the source-side selection transistor STS are connected in series via the semiconductor body 20 of one columnar part CL to constitute one memory string. Such memory strings are arrayed, for example, in a staggered manner in a planar direction parallel to an XY plane and the memory cells MC are provided three-dimensionally in the X-direction, the Y-direction, and the Z-direction.

The lower region 20a of the semiconductor body 20 is explained below. FIG. 3B is a schematic sectional view of a portion in a dashed frame B in FIG. 2. The lower region 20a of the semiconductor body 20 is in contact with the semiconductor layer 13 having n-type impurities (for example, phosphorus) doped thereto and the lower region 20a also includes n-type impurities. The lower region 20a is a semiconductor body 20 positioned below the source-side selection gate SGS or the gate layer 80 in the semiconductor body 20. The impurity concentration of the lower region 20a is higher than those of the source layer SL (the semiconductor layers 12 to 14) positioned therearound. The n-type impurity concentration of the lower region 20a is higher than that of the upper region 20b (a channel for the memory cells MC and the drain-side selection transistor STD) of the semiconductor body 20. This is because highly-concentrated n-type impurities are selectively solid-phase diffused to the lower region 20a from the inner parts of memory holes MH, as will be described later. The upper region 20b is a part of the semiconductor body 20 positioned above the lower region 20a and is positioned above the source-side selection gate SGS or the gate layer 80.

In this way, the lower region 20a of the semiconductor body 20 is electrically connected to the source layer SL (the semiconductor layer 13) in a direction (the Y-direction) substantially perpendicular to the stacking direction (the Z-direction). The connection part between the lower region 20a and the source layer SL is denoted by CON. Because the n-type impurity concentration of the lower region 20a is higher than that of the semiconductor layer 13, the n-type impurity concentration of the connection part CON is lower than the impurity concentration of the lower region 20a and higher than that of the semiconductor layer 13. That is, the connection part CON has a concentration gradient where the n-type impurity concentration lowers from the lower region 20a to the semiconductor layer 13.

While being diffused to some extent in the Z-direction to reach the semiconductor body 20 facing the source-side selection gate SGS, the n-type impurities (for example, phosphorus) are not greatly diffused to the semiconductor body 20 facing the electrode layers 70 that function as gates (word lines) of the memory cells MC. That is, while the n-type impurities may be diffused to channels of some of the source-side selection transistors STS, the n-type impurities are adjusted not to be diffused to the channels of all the source-side selection transistors STS. While the n-type impurities are diffused to some extent in the upper region 20b of the semiconductor body 20 as will be described later, p-type impurities are counter-doped. Accordingly, the upper region 20b includes both the n-type impurities and the p-type impurities and has a substantially neutral conductivity type. Alternatively, while the upper region 20b includes both the n-type impurities and the p-type impurities, the p-type impurity concentration is higher than the n-type impurity concentration and the upper region 20b is a slightly p-type semiconductor. The impurity concentration (for example, 10²⁰ to 10²¹/cm³) of the lower region 20a is higher than the impurity concentration (for example, 10¹⁷ to 10¹⁹/cm³) of the upper region 20b by double digits or more. Therefore, a steep concentration gradient (joint part) is provided between the lower region 20a and the upper region 20b. This enables the GIDL to be efficiently generated at the time of an erase operation.

At the time of a read operation, electrons are supplied from the source layer SL to the channels of the memory cells MC through the lower region 20a of the semiconductor body 20. At this time, with application of an appropriate potential to the gate layer 80, the channel (n-channel) can be induced in the entire region of the upper region 20b of the semiconductor body 20. The memory film 30 between the upper region 20b of the semiconductor body 20 and the gate layer 80 functions as a gate dielectric film.

The gate layer 80 functions as an etching stopper at the time of forming slits ST1 and ST2 described later. Accordingly, the gate layer 80 is formed relatively thickly and has, for example, a thickness of about 200 nanometers. Because the gate layer 80 is thick, the semiconductor layer 14 can be formed thinly. The thickness of the semiconductor layer 14 is, for example, about 30 nanometers.

For example, positive holes that are generated by applying an erase potential (for example, several volts) to the gate layer 80 and applying a high electric field to the upper region 20b of the semiconductor body 20 are supplied to the channels of the memory cells MC and increase the channel potential. By then setting the potential of the cell gates CG to, for example, a ground potential (0 volt), the positive holes are input to the charge accumulation film 32 due to the potential difference between the semiconductor body 20 and the cell gates CG, and a data erase operation is performed. That is, an erase operation due to the GIDL is performed.

A manufacturing method of the semiconductor storage device is explained next.

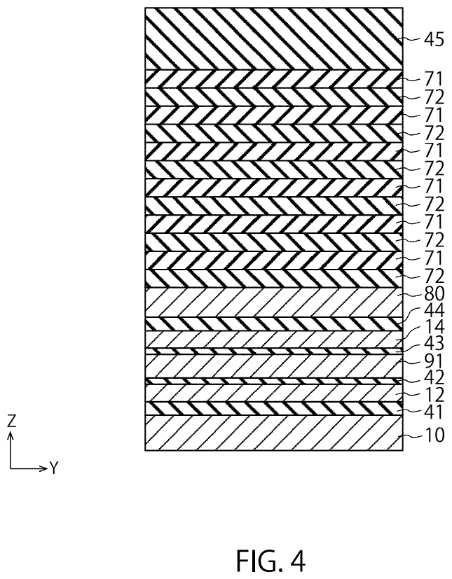

FIGS. 4 to 20 are sectional views illustrating an example of the manufacturing method of the semiconductor storage device according to the first embodiment. In FIGS. 4 to 20, one columnar part CL, one insulating part 160, and one wiring part 170 are illustrated side by side for convenience sake. Practically, the insulating part 160 or the wiring part 170 is provided on both sides of each of a plurality of columnar parts CL arranged in a staggered manner in a planar layout seen from above the substrate 10.

As illustrated in FIG. 4, the insulating layer 41 is formed on the substrate 10. The semiconductor layer 12 is formed on the insulating layer 41. The semiconductor layer 12 is, for example, a phosphorus-doped polycrystalline silicon layer. The thickness of the semiconductor layer 12 is, for example about 200 nanometers.

A protective film 42 is formed on the semiconductor layer 12. The protective film 42 is, for example, a silicon dioxide film.

A sacrifice layer 91 is formed on the protective film 42 above the substrate 10. The sacrifice layer 91 is, for example, an undoped polycrystalline silicon layer. The thickness of the sacrifice layer 91, for example, about 30 nanometers.

A protective film 43 is formed on the sacrifice layer 91. The protective film 43 is, for example, a silicon dioxide film.

The semiconductor layer 14 is formed on the protective film 43. The semiconductor layer 14 is, for example, an undoped or phosphorus-doped polycrystalline silicon layer. The thickness of the semiconductor layer 14 is, for example, about 30 nanometers.

The insulating layer 44 is formed on the semiconductor layer 14. The insulating layer 44 is, for example, a silicon dioxide film.

The gate layer 80 (a conductive layer such as a semiconductor layer or a metal gate layer) is formed on the insulating layer 44 above the sacrifice layer 91. The gate layer 80 is, for example, a phosphorus-doped polycrystalline silicon layer. The thickness of the gate layer 80 is larger than that of the semiconductor layer 14 and that of the insulating layer 44 and is, for example, about 200 nanometers.

The stacked body 100 is formed on the gate layer 80. The insulating layer 72 and a sacrifice layer 71 are alternately stacked on the gate layer 80. The process of alternately stacking the insulating layer 72 and the sacrifice layer 71 is repeated, whereby a stacked body including a plurality of the sacrifice layers 71 and a plurality of the insulating layers 72 is formed on the gate layer 80. The insulating layer 45 is formed on the topmost sacrifice layer 71. For example, the sacrifice layers 71 are silicon nitride layers and the insulating layers 72 are silicon dioxide layers. The thickness of the gate layer 80 is larger than that of one sacrifice layer 71 and that of one insulting layer 72. Accordingly, a structure illustrated in FIG. 4 is obtained.

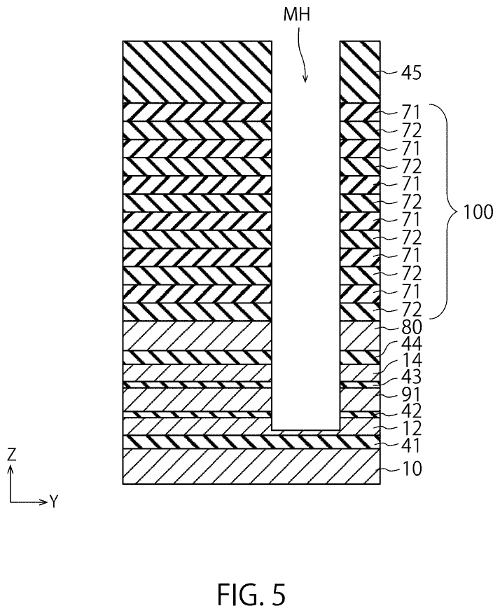

Next, a plurality of memory holes MH extending from the insulating layer 45 to the semiconductor layer 12 are formed as illustrated in FIG. 5. The memory holes MH are formed by a lithography technology and an etching technology (for example, an RIE (Reactive Ion Etching) method). The memory holes MH penetrate through the insulating layer 45, the stacked body 100, the gate layer 80, the insulating layer 44, the semiconductor layer 14, and the protective film 43 to reach the sacrifice layer 91 and further penetrate through the sacrifice layer 91 and the protective film 42 to reach the semiconductor layer 12. The bottoms of the memory holes MH are located in the semiconductor layer 12.

The sacrifice layers (silicon nitride layers) 71 and the insulating layers (silicon dioxide layers) 72 are continuously etched with a same gas (for example, a CF-based gas) without changing the gas type. At this time, the gate layer (polycrystalline silicon layer) 80 functions as an etching stopper and temporarily stops the etching at the location of the gate layer 80. Variation of the etching rate among the memory holes MH is absorbed by the thick gate layer 80 and variation of the bottom location among the memory holes MH is reduced.

Thereafter, the gas type is changed to perform step-etching of layers. That is, the remaining part of the gate layer 80 is etched using the insulating layer 44 as a stopper, the insulating layer 44 is etched using the semiconductor layer 14 as a stopper, the semiconductor layer 14 is etched using the protective film 43 as a stopper, the protective film 43 is etched using the sacrifice layer 91 as a stopper, the sacrifice layer 91 is etched using the protective film 42 as a stopper, and the protective film 42 is etched using the semiconductor layer 12 as a stopper. The etching is stopped in the middle of the thick semiconductor layer 12.

The thick gate layer 80 facilitates control of the etching stop position in hole processing for the stacked body 100 having a high aspect ratio.

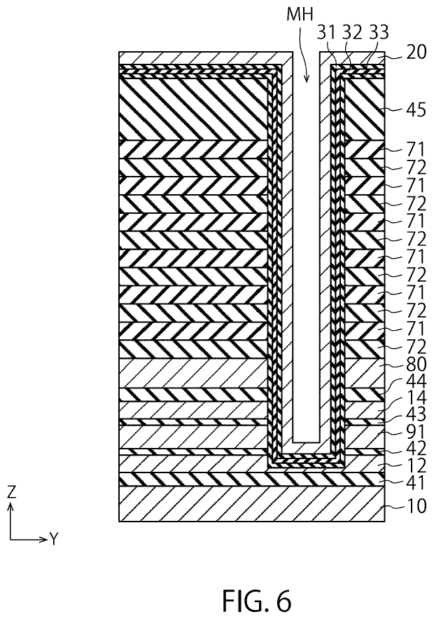

Next, materials of the block dielectric film 33, the charge accumulation film 32, the tunnel dielectric film 31, and the semiconductor bodies 20 are conformally formed in this order along the inner surfaces and bottoms of the memory holes MH as illustrated in FIG. 6.

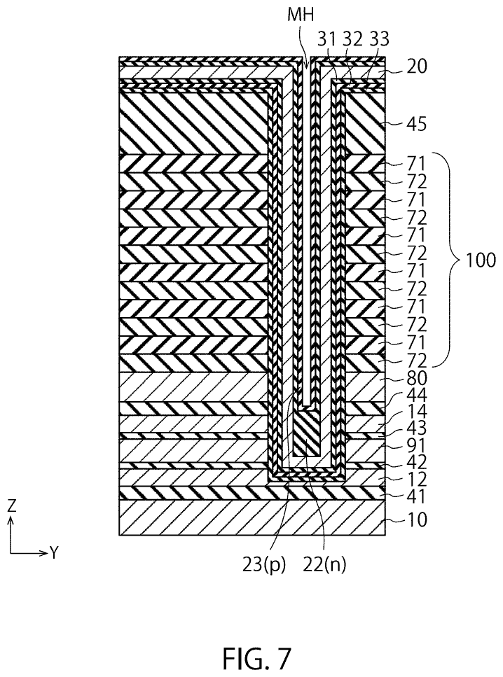

Subsequently, as illustrated in FIG. 7, an n-type dopant material 22 containing highly-concentrated n-type impurities is applied to the semiconductor bodies 20 by spin-coat processing, whereby the n-type dopant material 22 is accumulated in the bottoms of the memory holes MH. The n-type dopant material 22 can be, for example, a film containing an oxide of phosphorus. A p-type dopant material 23 can be, for example, a film containing an oxide of boron. A film thickness (the film thickness in the Z-direction) of the n-type dopant material 22 formed at the bottoms of the memory holes MH are formed to be larger than a film thickness (the film thickness in the Y-direction) of the n-type dopant material 22 formed on the side surfaces of the memory holes MH.

The top surface of the n-type dopant material 22 accumulated in the bottoms of the memory holes MH is located at a position lower than the top surface of the gate layer 80 and higher than the top surface of the sacrifice layer 91. The n-type dopant material 22 can be accumulated in the bottoms of the memory holes MH by addition of an additive. The film thickness (the height in the Z-direction) of the n-type dopant material 22 at the bottoms of the memory holes MH can be adjusted by a spin rate or the like of the substrate 10 in the process of applying the n-type dopant material 22.

The substrate 10 is thereafter baked to vaporize the solvent for the n-type dopant material 22.

While the n-type dopant material 22 does not need to coat the side surfaces of the memory holes MH, the n-type dopant material 22 resultantly remains thinly thereon in some cases. In these cases, the p-type dopant material 23 containing highly-concentrated p-type impurities having a conductivity type opposite to the n-type impurities is applied over the n-type dopant material 22 by the spin-coat processing as illustrated in FIG. 7. At this time, the p-type dopant material 23 is thinly applied on the bottom surfaces and side surfaces of the memory holes MH so as not to be accumulated in the bottoms of the memory holes MH. The n-type impurity concentration of the lower regions 20a can be controlled by the film thickness of the n-type dopant material 22, the temperature or time of heat treatment, and the n-type impurity concentration in the solution of the n-type dopant material 22. The p-type dopant material 23 can be conformally formed in the memory holes MH without addition of an additive.

After the p-type dopant material 23 is applied onto the n-type dopant material 22, the substrate 10 is baked to vaporize the solvent for the p-type dopant material 23.

While the p-type dopant material 23 is applied after the n-type dopant material 22 is applied in the present embodiment, the n-type dopant material 22 can be applied after the p-type dopant material 23 is applied. That is, the location relation between the n-type dopant material 22 and the p-type dopant material 23 in FIG. 7 can be opposite. However, the n-type dopant material 22 is thickly formed at the bottoms of the memory holes MH and the p-type dopant material 23 is thinly and conformally formed on the inner surfaces of the memory holes MH, similarly in the embodiment described above.

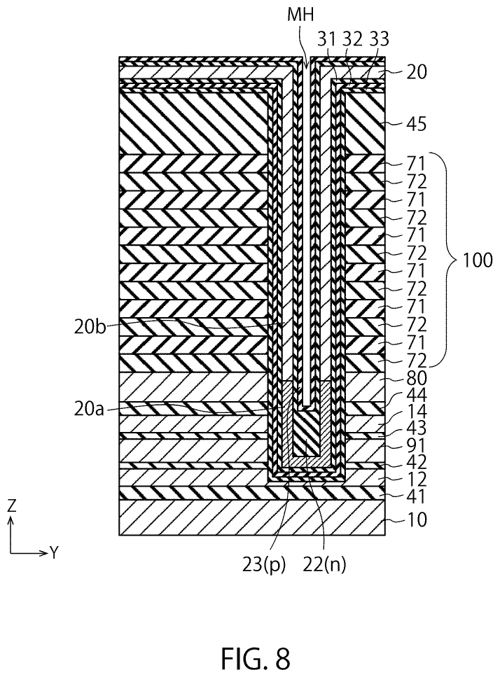

Next, heat treatment for diffusing the impurities in the coated film is performed as illustrated in FIG. 8. With this heat treatment, the n-type impurities are diffused from the thick n-type dopant material 22 remained in the bottoms of the memory holes MH to the lower regions 20a of the semiconductor bodies 20. This brings the lower regions 20a of the semiconductor bodies 20 to highly-concentrated n-type semiconductor layers. Solid-phase diffusion from the n-type dopant material 22 to the semiconductor bodies 22 may be achieved by heat treatment at a relatively low temperature (for example, 750° C. to 850° C.). Therefore, even in a case in which a CMOS (Complementary Metal Oxide Semiconductor) circuit is formed on the substrate 10, the n-type impurities can be diffused to the lower regions 20a of the semiconductor bodies 20 without affecting the CMOS circuit (not illustrated).

Meanwhile, the n-type dopant material 22 and the p-type dopant material 23 of similar thicknesses are stacked on the side surfaces of the memory holes MH positioned above the lower regions 20a. Therefore, both the n-type impurities and the p-type impurities are mixed in similar concentrations on the upper regions 20b above the lower regions 20a in the inner surfaces of the memory holes MH and the conductivity type is substantially neutral. Either the p-type or n-type may be more concentrated for threshold adjustment. Accordingly, the lower regions 20a of the semiconductor bodies 20 can be selectively formed as highly-concentrated n-type impurity layers. Further, the semiconductor bodies 20 (the upper regions 20b) being substantially neutral in the conductivity type are formed on the inner surfaces of the memory holes MH higher than the lower regions 20a, respectively. The lower regions 20a are formed from the bottoms of the semiconductor bodies 20 to the middle of the gate layer 80, and the upper regions 20b are formed above the lower regions 20a. A steep concentration gradient (a p-n junction) is formed between the lower regions 20a and the upper regions 20b.

It is considered that, after the n-type dopant material 22 is applied, the n-type dopant material 22 accumulated in the bottoms of the memory holes MH is remained and the thin n-type dopant material 22 on the side surfaces of the memory holes MH is selectively etched back with a wet etching solution. However, the etching rate of the n-type dopant material 22 accumulated in the bottoms of the memory holes MH is practically relatively high and it is difficult to selectively remove the n-type dopant material 22 on the side surfaces of the memory holes MH. Therefore, it is preferable to thinly apply the p-type dopant material 23 and to counter-dope the p-type impurities to the side surfaces of the memory holes MH against the n-type impurities.

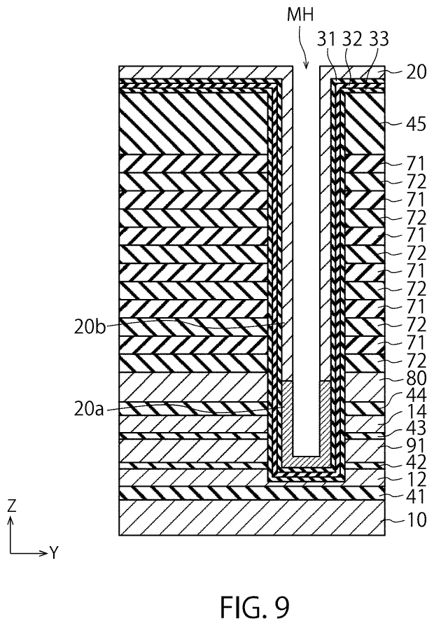

Next, the p-type dopant material 23 and the n-type dopant material 22 are removed by a wet etching method or the like as illustrated in FIG. 9.

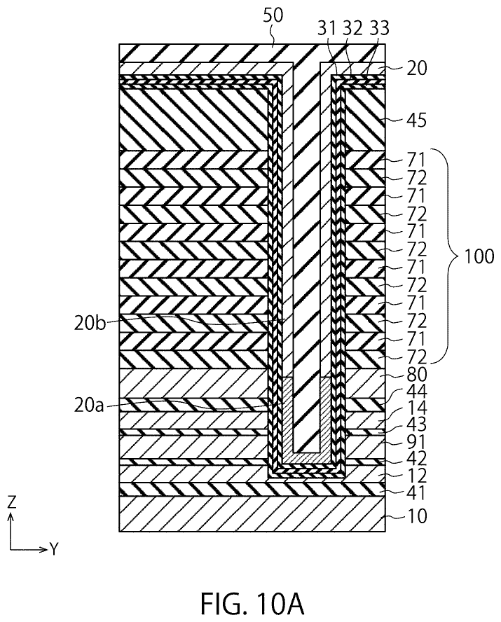

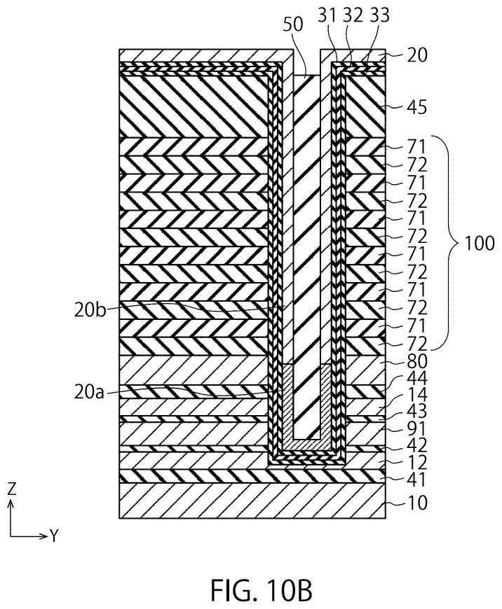

Subsequently, the core film 50 is formed on the semiconductor bodies 20 to fill the inner parts of the memory holes MH as illustrated in FIG. 10A. The core film 50 is, for example, an insulating film such as a silicon dioxide film.

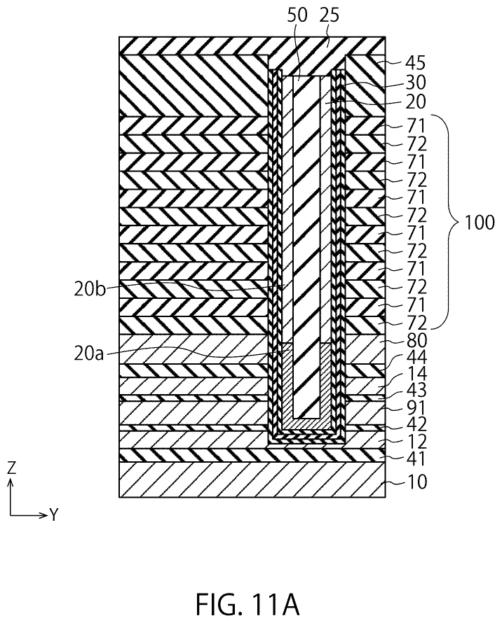

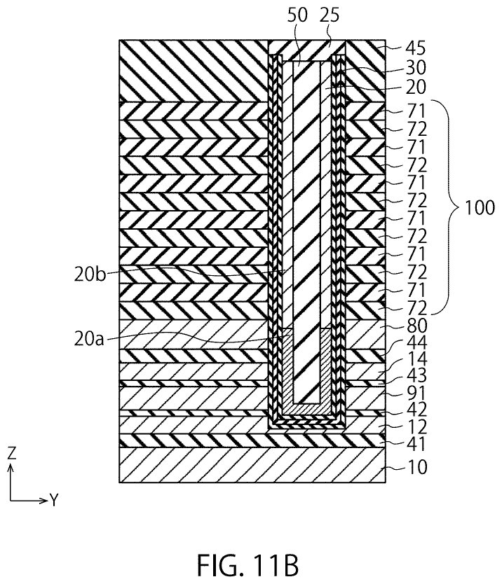

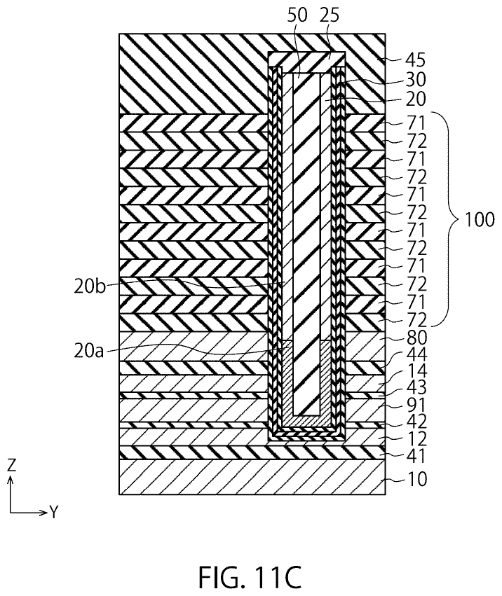

Next, the core film 50 is etched back as illustrated in FIG. 10B. Further, a cap film 25 is deposited on the core film 50 and the insulating film 45 as illustrated in FIG. 11A. The cap film 25 is, for example, amorphous silicon and may be doped with phosphorus (P) or the like to provide conductivity. As illustrated in FIG. 11B, the cap film 25 on the surface, the semiconductor bodies 20, and the memory film 30 are removed by etching according to RIE (Reactive Ion Etching) processing. Next, the insulating film 45 is further formed on the cap film 25 and the insulating film 45 as illustrated in FIG. 11C. For example, a silicon dioxide film is formed as the insulating film 45.

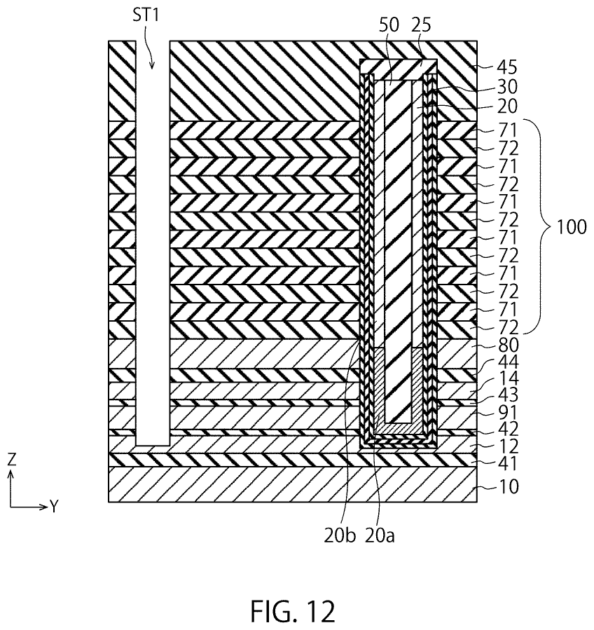

Next, a plurality of slits ST1 are formed in the stacked body 100 using the lithography technology and the etching technology as illustrated in FIG. 12. The slits ST1 penetrate through the insulating layer 45, the stacked body 100, the gate layer 80, the insulating layer 44, the semiconductor layer 14, the semiconductor layer 13, the protective films 42 and 43, and the sacrifice layer 91 to reach the semiconductor layer 12. Although one slit ST1 is illustrated in FIG. 12, a plurality of the slits ST1 are provided at substantially equal intervals with respect to a predetermined number of the columnar parts CL.

At this time, the sacrifice layers 71 and the insulating layers 72 are continuously etched using a same gas (for example, a CF-based gas) without changing the gas type, similarly in the formation of the memory holes MH. The gate layer 80 functions as an etching stopper and temporarily stops etching of the slits ST1 at the location of the gate layer 80. The thick gate layer 80 absorbs variation of the etching rate among the slits ST1 and variation of the bottom location among the slits ST1 is reduced.

Next, layers are step-etched while the gas type is changed. That is, the remaining part of the gate layer 80 is etched using the insulating layer 44 as a stopper. The insulating layer 44 is exposed on the bottoms of the slits ST1. Thereafter, the insulating layer 44 is etched using the semiconductor layer 14 as a stopper, and the semiconductor layer 14 is etched using the protective film 43 as a stopper. Further, the protective film 43 is etched using the sacrifice layer 91 as a stopper, the sacrifice layer 91 is etched using the protective film 42 as a stopper, and the protective film 42 is etched using the semiconductor layer 12 as a stopper. Accordingly, the semiconductor layer 12 is exposed on the bottoms of the slits ST1. The slits ST1 are formed to the middle of the semiconductor layer 12.

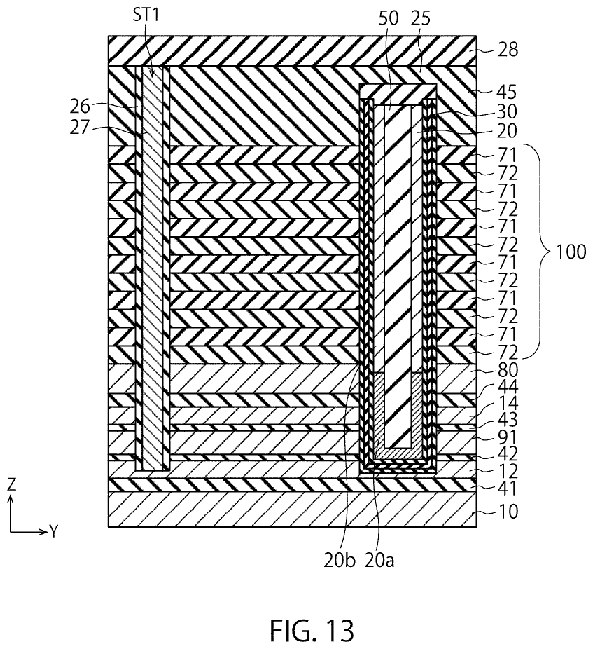

Next, the insulting film 26 is formed entirely on the inner surfaces of the slits ST1 as illustrated in FIG. 13. The insulating film 26 is, for example, an insulating film such as a silicon oxide film. Next, the insulating film 26 is anisotropically etched back. Accordingly, the insulating film 26 on the bottoms of the slits ST1 is removed to expose the semiconductor layer 12. Meanwhile, the insulating film 26 on the side surfaces of the slits ST1 is remained. Subsequently, doped polysilicon or a metallic material is filled in the slits ST1 as a material of the wiring layer 27. Accordingly, the wiring layer 27 is electrically connected to the semiconductor layer 12 while being electrically insulated by the insulating film 26 from the stacked body 100, the gate layer 80, and the semiconductor layer 14 in the slits ST1. The insulating film 26 and the wiring layer 27 are used as the wiring parts 170 (see FIG. 2) for applying a voltage to the semiconductor layer 12. Next, the insulating film 28 is formed on the slits ST1 and the insulating layer 45. Accordingly, a structure illustrated in FIG. 13 is obtained.

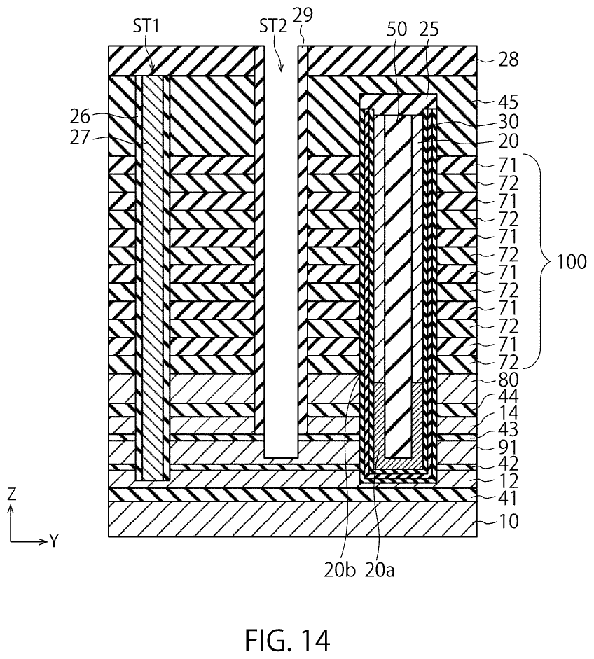

Next, a plurality of slits ST2 are formed in the stacked body 100 using the lithography technology and the etching technology as illustrated in FIG. 14. The slits ST2 penetrate through the insulating films 28 and 45, the stacked body 100, the gate layer 80, the insulating layer 44, the semiconductor layer 14, the semiconductor layer 13, and the protective films 42 and 43 in the stacking direction of the stacked body 100 to reach the sacrifice layer 91. Although only one slit ST2 is illustrated in FIG. 14, a plurality of the slits ST2 are provided at substantially equal intervals with respect to a predetermined number of the columnar parts CL.

The process of forming the slits ST2 is substantially same as the process of forming the slits ST1. However, after the protective film 43 is etched using the sacrifice layer 91 as a stopper, the slits ST2 are formed to the middle of the sacrifice layer 91. The slits ST2 are not formed to the semiconductor layer 12.

Next, an insulating film 29 is formed on the entire inner surfaces of the slits ST2 as illustrated in FIG. 14. The insulating film 29 is, for example, an insulating film such as a silicon nitride film. Next, the insulating film 29 is anisotropically etched back. Accordingly, the insulating film 29 on the bottoms of the slits ST2 is removed to expose the sacrifice layer 91. Meanwhile, the insulating film 29 on the side surfaces of the slits ST2 is remained.

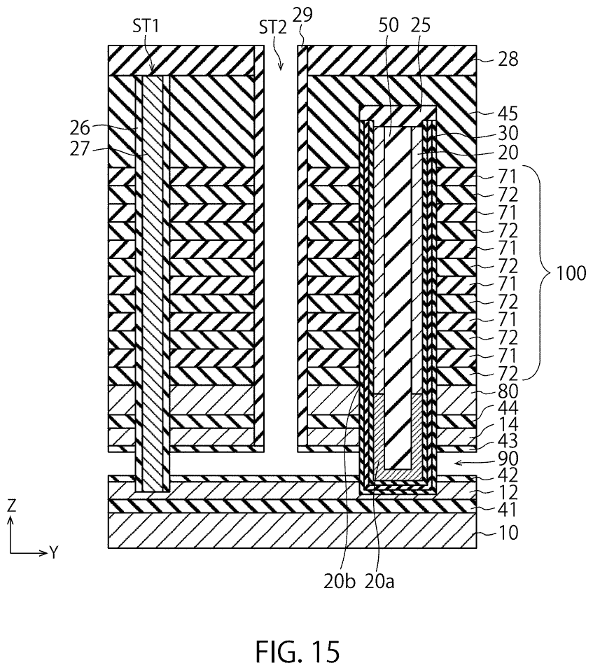

Subsequently, the sacrifice layer 91 is removed through the slits ST2 using the wet etching method as illustrated in FIG. 15. When the sacrifice layer 91 is polysilicon, the etching solution can be, for example, hot TMY (trimethyl (2-hydroxyethyl) ammonium hydroxide). Accordingly, the sacrifice layer 91 is removed and voids 90 are formed at the location of the sacrifice layer 91. At this time, the insulating film 29 protects the side surfaces of the slits ST2 to prevent the stacked body 100, the gate layer 80, and the semiconductor layer 14 from being etched. The protective films 42 and 43 protect the semiconductor layers 12 and 14 to prevent the semiconductor layers 12 and 14 from being etched, respectively. A part of the sidewalls of the columnar parts CL, that is, a part of the memory film 30 is exposed in the voids 90.

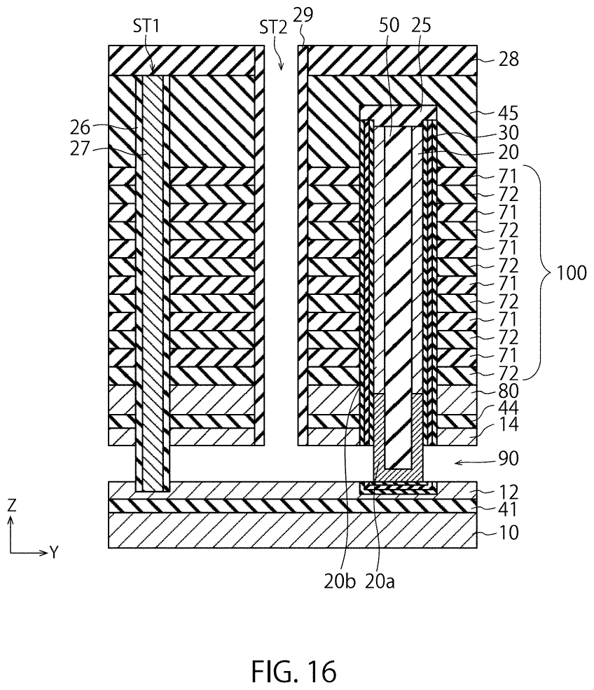

Next, the part of the memory film 30 exposed in the voids 90 is removed through the slits ST2 using an isotropic etching method as illustrated in FIG. 16. For example, the memory film 30 is etched by a CDE (Chemical Dry Etching) method. At this time, the protective films 42 and 43 being a same type as that of a film included in the memory film 30 are also removed. The insulating film 29 formed on the side surfaces of the slit ST2 is a silicon nitride film being a same type as that of the charge accumulation film 32 included in the memory film 30. However, because the film thickness of the insulating film 29 is larger than that of the charge accumulation film 32, the insulating film 29 remains on the side surfaces of the slits ST2.

The insulating film 29 protects the stacked body 100, the gate layer 80, and the insulating layer 44 and suppresses side etching thereof at the time of removing the part of the memory film 30 exposed in the voids 90. Further, because the semiconductor layer 14 covers the bottom surface of the insulating layer 44, etching of the insulating layer 44 from the bottom surface side is also suppressed.

Due to removal of the part of the memory film 30, a part of the lower regions 20a is exposed in the voids 90. That is, the memory film 30 is split in the vertical direction in a part of the lower regions 20a as illustrated in FIG. 16. The memory film 30 between the gate layer 80 and each of the semiconductor bodies 20 is prevented from being etched by control of the etching time.

Also below the lower regions 20a, the memory film 30 is caused to remain between the semiconductor layer 12 and the lower regions 20a of the semiconductor bodies 20 by control of the etching time. A state in which the lower ends of the semiconductor bodies 20 below the lower regions 20a are supported by the semiconductor layer 12 with the memory film 30 interposed therebetween is maintained.

When the part of the memory film 30 is removed, a part of the lower regions 20a of the semiconductor bodies 20 is exposed in the voids 90.

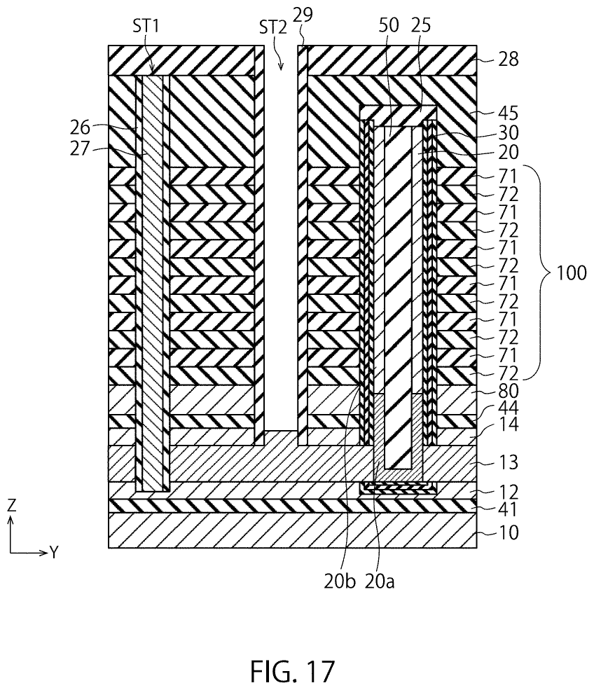

The semiconductor layer 13 is formed in the voids 90 as illustrated in FIG. 17. The semiconductor layer 13 is formed below the gate layer 80 and connects to the lower regions 20a. The semiconductor layer 13 is, for example, a phosphorus-doped polycrystalline silicon layer.

A gas containing silicon is supplied to the voids 90 through the slits ST2 and the semiconductor layer 13 epitaxially grows from the top surface of the semiconductor layer 12, the bottom surface of the semiconductor layer 14, and the lower regions 20a of the semiconductor bodies 20 exposed in the voids 90 and the voids 90 are filled with the semiconductor layer 13.

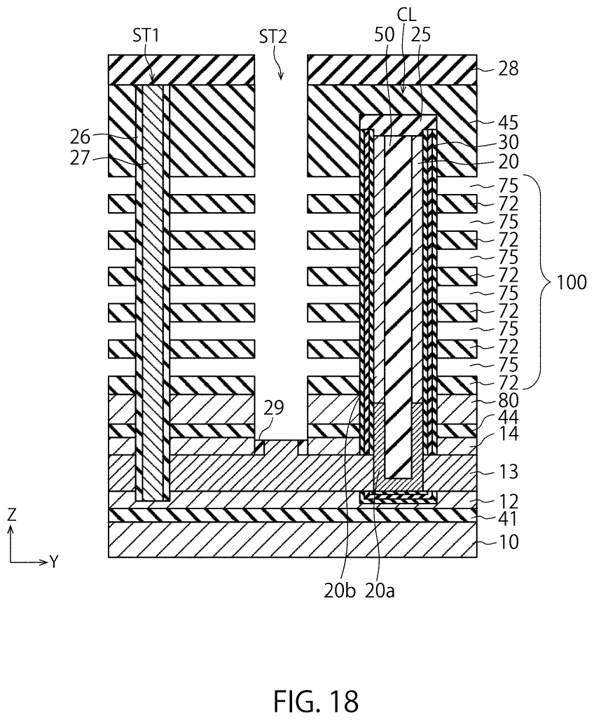

Next, after removal of the insulating film 29 or following the removal, the sacrifice layers 71 are removed with an etching solution or an etching gas supplied through the slits ST2. For example, the sacrifice layers 71 being silicon nitride layers are removed using a hot phosphoric acid solution. Accordingly, the sacrifice layers 71 are removed and voids 75 are formed between the insulating layers 72 adjacent in the vertical direction as illustrated in FIG. 18. The void 75 is also formed between the topmost insulating layer 72 and the insulating layer 45.

The insulating layers 72 are in contact with the side surfaces of the columnar parts CL to enclose the side surfaces of the columnar parts CL. The insulating layers 72 are supported by this physical binding with the columnar parts CL and the voids 75 between the insulating layers 72 are maintained.

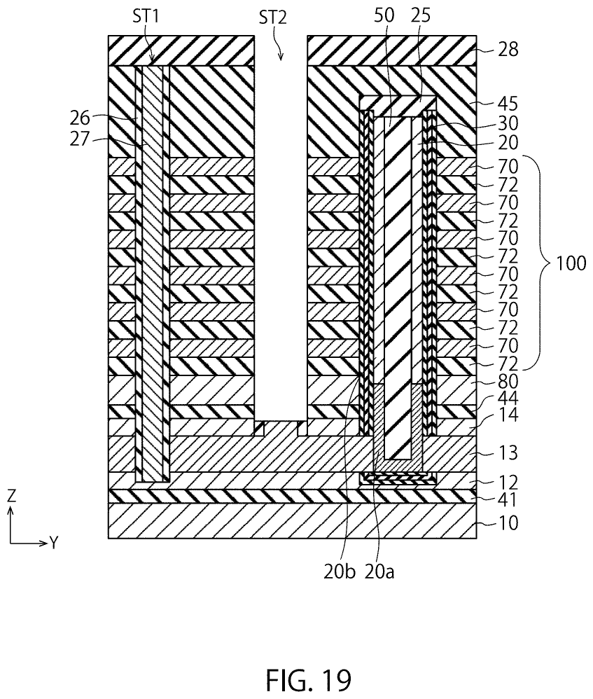

Next, the electrode layers 70 are embedded in the voids 75 as illustrated in FIG. 19. For example, a source gas is supplied to the voids 75 through the slits ST2 and the electrodes 70 are formed by a CVD (Chemical Vapor Deposition) method between the insulating layers 72 adjacent in the stacking direction of the stacked body 100. The electrode layers 70 formed on the side surfaces of the slits ST2 (the side surfaces of the insulating layers 72) are removed.

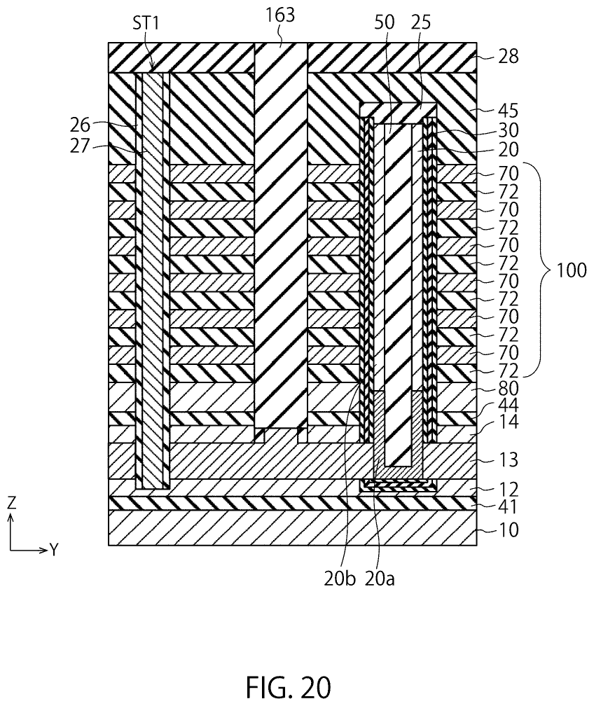

Subsequently, the insulating film 163 is embedded in the slits ST2 to form the insulating parts 160 as illustrated in FIG. 20. Thereafter, a multilayer wiring structure is further formed on the insulating layer 45 and the like, whereby the semiconductor storage device according to the present embodiment is completed.

As described above, according to the present embodiment, the n-type impurities are diffused from the n-type dopant material 22 formed in the memory holes MH to the lower regions 20a of the semiconductor bodies 20. The n-type dopant material 22 is formed thickly at the bottoms of the memory holes MH and is formed significantly thinly on the side surfaces thereof. Therefore, the n-type impurity concentration of the lower regions 20a is higher than those of the semiconductor layer 13 and the upper regions 20b.

The p-type dopant material 23 is formed on the n-type dopant material 22 on the side surfaces of the memory holes MH. The p-type dopant material 23 diffuses the p-type impurities to the upper regions 20b of the semiconductor bodies 20 as a counter dope against the n-type impurities from the n-type dopant material 22. Accordingly, the upper regions 20b contain both the n-type impurities and the p-type impurities and have a substantially neutral conductivity type. Therefore, a steep concentration gradient is formed between the lower regions 20a and the upper regions 20b and the GIDL can be efficiently generated.

If the n-type impurities are to be diffused from the semiconductor layer 13 outside the memory holes MH to the semiconductor bodies 20, high-temperature heat treatment at a temperature equal to or higher than 850° C. is required and there is a risk that the characteristics of the CMOS circuit below the memory cell array 1 are affected. Further, even if the high-temperature heat treatment is possible, it is difficult to control the diffusion amount in a case of diffusing the n-type impurities from the semiconductor layer 13 to the semiconductor bodies 20. Therefore, there is a risk that the n-type impurities are diffused to a part above the gate layer 80, which deteriorates the cutoff characteristic of the source-side selection transistors STS.

Further, the ion implantation method has a difficulty in reliably implanting impurities to the bottoms of the memory holes MH having a high aspect ratio.

In contrast thereto, diffusion of impurities from the inner parts of the memory holes MH using the n-type dopant material 22 as in the present embodiment enables the impurities to be diffused to the semiconductor bodies 20 at a relatively low temperature equal to or lower than 850° C. with a high controllability. Accordingly, the height location of a steep concentration gradient between the lower regions 20a and the upper regions 20b can be adapted to the location of the source layer SL or the gate layer 80. Further, influences on the CMOS circuit (a peripheral circuit region) below the memory cell array 1 are small.

The n-type impurities are solid-phase diffused to the lower regions 20a using the n-type dopant material 22 in the present embodiment. Therefore, damages on the semiconductor bodies 20 due to ion implantation are small.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a first semiconductor layer containing impurities;
a stacked body provided above the first semiconductor layer, and including insulating layers and conductive layers that are alternately stacked;
a semiconductor body penetrating through the stacked body in a stacking direction to reach the first semiconductor layer, and including a lower region on a side of the first semiconductor layer and an upper region positioned above the lower region; and
a charge accumulation part provided between the semiconductor body and the conductive layers, wherein
an impurity concentration of the lower region of the semiconductor body is higher than that of the first semiconductor layer.

2. The device of claim 1, wherein the impurity concentration of the lower region is higher than that of the upper region of the semiconductor body.

3. The device of claim 1, wherein the upper region include both a n-type impurity and a p-type impurity.

4. The device of claim 2, wherein the upper region include both a n-type impurity and a p-type impurity.

5. The device of claim 1, further comprising a connection part connecting the first semiconductor layer and the lower region in a direction crossing the stacking direction.

6. The device of claim 2, further comprising a connection part connecting the first semiconductor layer and the lower region in a direction crossing the stacking direction.

7. The device of claim 3, further comprising a connection part connecting the first semiconductor layer and the lower region in a direction crossing the stacking direction.

8. The device of claim 5, wherein an impurity concentration of the connection part is lower than that of the lower region and higher than that of the first semiconductor layer.

9. The device of claim 6, wherein an impurity concentration of the connection part is lower than that of the lower region and higher than that of the first semiconductor layer.

10. The device of claim 7, wherein an impurity concentration of the connection part is lower than that of the lower region and higher than that of the first semiconductor layer.

11. A semiconductor storage device comprising:
a first semiconductor layer containing impurities;
a stacked body provided above the first semiconductor layer, and including insulating layers and conductive layers that are alternately stacked;
a semiconductor body penetrating through the stacked body in a stacking direction to reach the first semiconductor layer, and including a lower region on a side of the first semiconductor layer and an upper region positioned above the lower region; and
a charge accumulation part provided between the semiconductor body and the conductive layers, wherein
an impurity concentration of the lower region of the semiconductor body is higher than that of the upper region,
the lower region including a n-type impurity, and
the upper region including both of a n-type impurity and a p-type impurity.

12. The device of claim 11, further comprising a connection part connecting to the lower region in a direction crossing the stacking direction.

13. The device of claim 12, wherein an impurity concentration of the connection part is lower than that of the lower region.

14. A manufacturing method of a semiconductor storage device, the method comprising:
forming a first sacrifice layer above a substrate;
alternately stacking insulating layers and second sacrifice layers to form a stacked body above the first sacrifice layer;
forming a hole penetrating through the second sacrifice layers in a stacking direction to reach the first sacrifice layer;
forming a charge accumulation layer on inner surfaces of the holes;
forming a semiconductor body on the charge accumulation layer on the inner surface of the holes;
after forming the semiconductor body, forming a first impurity-containing layer in the hole to be thicker at bottom of the hole than on side surfaces of the hole;
thermally treating the first impurity-containing layer; and
removing the first impurity-containing layer.

15. The method of claim 14, further comprising:
after forming the first impurity-containing layer,
forming a second impurity-containing layer on the side surface of the hole, the second impurity-containing layer containing a second impurity of a different conductivity type to that of the first impurity; and
removing the first and second impurity-containing layer after thermally treating the first and second impurity-containing layer.

16. The method of claim 14, wherein the first impurity-containing layer is formed by spin-coat processing.

17. The method of claim 15, wherein the second impurity-containing layer is formed by spin-coat processing.

18. The method of claim 14, wherein the first impurity is diffused from the first impurity-containing layer to a lower region of the semiconductor body by the thermal treatment.

19. The method of claim 15, wherein both the first impurity and the second impurity are diffused from the first and second impurity-containing layer to an upper region positioned above the lower region of the semiconductor body in the thermal treatment.

20. The method of claim 18, further comprising:
forming a slit penetrating through the stacked body in the stacking direction to reach the first sacrifice layer;
removing the first sacrifice layer and the charge accumulation layer through the slit to expose a part of the lower region; and
forming a first semiconductor layer being in contact with the part of the lower region through the slit.
